(19) United States
(12) Patent Application Publication
(10) Pub. No.: US 2018/0373362 A1
(43) Pub. Date: Dec. 27, 2018

(54) OPERATION DEVICE

(71) Applicant: KABUSHIKI KAISHA TOKAI RIKA DENKI SEISAKUSHO, Aichi (JP)

(72) Inventor: Kunitoshi NOGUCHI, Aichi (JP)

(21) Appl. No.: 16/063,496

(22) PCT Filed: Jan. 11, 2017
(86) PCT No.: PCT/JP2017/000688

§ 371 Date: Jun. 18, 2018

(30) Foreign Application Priority Data
Jan. 14, 2016 (JP) 2016-005151

(51) Int. Cl. G06F 3/044; H03K 17/96; B60K 37/02

(52) U.S. Cl. CPC G06F 3/044; B60K 37/02; H03K 17/962

(57) ABSTRACT

An operation device includes a switch row in which operation switches are disposed, an electrostatic detection sensor disposed on an upper side or a lower side of the switch row and configured to detect two-dimensional coordinate values of an object to be detected coming close to the switch row, and a controller including a determination unit configured to determine which of the operation switches of the switch row is close to the object to be detected, based on a detection result of the electrostatic detection sensor.

### TECHNICAL FIELD

The present invention relates to an operation device.

### BACKGROUND ART

A capacitance switch is known that includes a transparent electrode provided on a translucent protective cover that covers a control target and a detection circuit that detects a variation in the capacitance to ground in the transparent electrode to output a detection signal for driving a control means. Such a capacitance switch is included in a known operation device (vehicle instrument) (see Patent Document 1). The operation device includes a display that displays vehicle operation information, a translucent protective cover disposed in front of the display that protects the display, the capacitance switch, and a controller. The capacitance switch includes a transparent electrode disposed on the translucent protective cover at a location facing the display and detects a variation in the capacitance to ground in the transparent electrode to output a detection signal. The controller controls a display of the display on the basis of a detection signal from the capacitance switch.

According to the operation device of Patent Document 1, the transparent electrode, disposed behind the transparent protective panel, detects capacitance and output it to a capacitance detection circuit. The capacitance increases as an object to be detected, such as a finger, comes close to the transparent protective panel. Accordingly, use and provision of a capacitance switch, configured to detect a variation of the capacitance to ground in the transparent electrode, for/to the translucent protective cover enables operation of the device without application of stress such as pressing force onto the translucent protective cover. In addition, the device is considered to provide an improved design, by concealing a switch unit from an external, and improved miniaturization of the switch unit.

### CITATION LIST

### Patent Literature

Patent Document 1: JP 2007-80808A

### SUMMARY OF INVENTION

### Technical Problem

The operation device disclosed in Patent Document 1 allows proximity detection of a finger or the like by the transparent electrode and this detection allows the operation device to perform operations such as renewal of display and turning light on and off, for example. However, the transparent electrode of the operation device (capacitance switch) is disposed immediately above the display, so that there is a possibility that proximity detection of a finger or the like and the detection of coordinates of the finger from the periphery of the display become difficult. In particular, when the operation device is used in a vehicle or the like, the installation area of the display is limited, and thus there is a high possibility that the proximity detection of a finger or the like and the detection of coordinates of the finger from the periphery of the display become difficult.

An object of the invention is to provide an operation device including an electrostatic detection sensor that allows proximity detection of a finger or the like from the periphery of a switch row.

### Solution to Problem

[1] An operation device according to an embodiment of the invention includes a switch row in which operation switches are disposed, an electrostatic detection sensor disposed on an upper side or a lower side of the switch row and configured to detect two-dimensional coordinate values of an object to be detected coming close to the switch row, and a controller including a determination unit, the determination unit being configured to determine whether the object to be detected comes closer to any of the operation switches of the switch row, based on a detection result of the electrostatic detection sensor.

[2] The operation device described in [1] may be such that the controller is configured to determine whether the object to be detected comes close to any of the operation switches of the switch row, based on a temporal change of the two-dimensional values from the electrostatic detection sensor.

[3] The operation device described in [1] or [2] may be such that the electrostatic detection sensor includes a first electrostatic detection sensor and a second electrostatic detection sensor disposed on an upper side and a lower side of the switch row, and the controller is configured to determine whether the object to be detected comes close to any of the operation switches of the switch row, based on detection results of the first electrostatic detection sensor and the second electrostatic detection sensor.

[4] The operation device described in any one of [1] to [3] may be such that the electrostatic detection sensor includes a detection sensor using a mutual capacitance method.

[5] The operation device described in any one of [1] to [4] may be such that the electrostatic detection sensor is formed outside of an area where the switch row is disposed. [6] The operation device described in any one of [1] to [5] may be such that the electrostatic detection sensor has a width exceeding a width of the switch row along a longitudinal direction.

### Advantageous Effects of Invention

According to an embodiment of the invention, the operation device including the electrostatic detection sensor that allows proximity detection of a finger or the like from the periphery of the switch row can be provided.

### BRIEF DESCRIPTION OF DRAWINGS

FIG. 1A is a block diagram illustrating a configuration of an operation device according to a first embodiment of the invention.

FIG. 1B is a plan view illustrating a sensor panel of the operation device according to the first embodiment of the invention.

FIG. 2 is an exploded perspective view illustrating a first detection electrode, a second detection electrode and an insulation layer of the operation device according to the first embodiment of the invention.

FIG. 3A is a plan view illustrating a wiring pattern of the first detection electrode.

FIG. 3B is a plan view illustrating a wiring pattern of the second detection electrode.

FIG. 4 is a plan view illustrating an example of capacitance distribution on the sensor panel in a case where a finger comes close to the sensor panel during the operation of the operation device according to the first embodiment of the invention.

FIG. 5A is a plan view illustrating a modification of the sensor panel of the operation device according to the first embodiment of the invention.

FIG. 5B is a plan view illustrating another modification of the sensor panel of the operation device according to the first embodiment of the invention.

FIG. 6A is a plan view illustrating a sensor panel of an operation device according to a second embodiment of the invention.

FIG. 6B is a plan view illustrating a state where a finger in close proximity moves to an operation switch.

FIG. 7 is a plan view illustrating a sensor panel of an operation device according to a third embodiment of the invention.

### DESCRIPTION OF EMBODIMENT

### First Embodiment of Invention

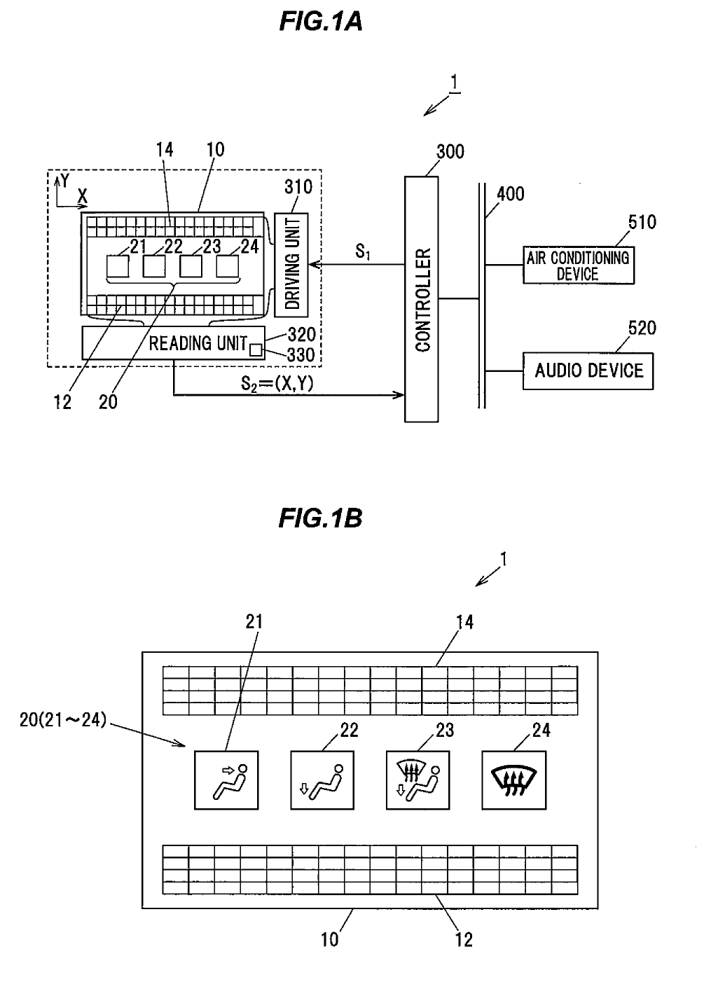

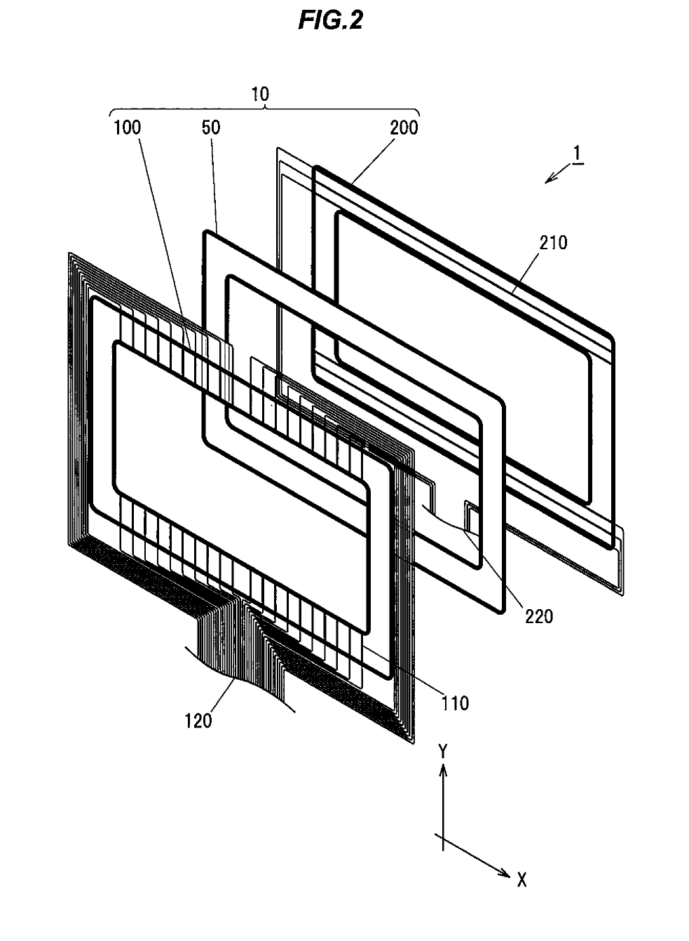

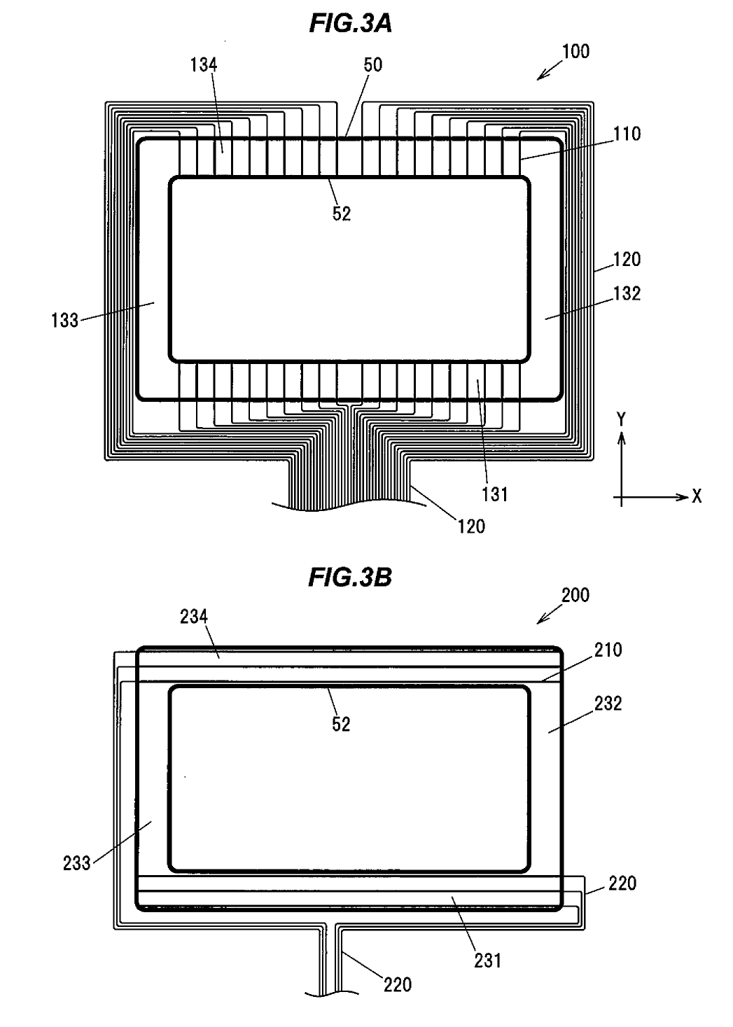

FIG. 1A is a block diagram illustrating a configuration of an operation device according to a first embodiment of the invention, and FIG. 1B is a plan view illustrating a sensor panel of the operation device according to the first embodiment of the invention. FIG. 2 is an exploded perspective view illustrating a first detection electrode, a second detection electrode and an insulation layer of the operation device according to the first embodiment of the invention. In addition, FIG. 3A is a plan view illustrating a wiring pattern of the first detection electrode, and FIG. 3B is a plan view illustrating a wiring pattern of the second detection electrode.

### Configuration of Operation Device 1

An operation device 1 according to the invention of the present application includes a switch row 20 in which a plurality of operation switches (21, 22, 23, and 24) are disposed, electrostatic detection sensors (a first electrostatic detection sensor 12 and a second electrostatic detection sensor 14) that are disposed on an upper side or a lower side of the switch row 20 and detect two-dimensional coordinate values of an object to be detected in close proximity such as a finger of an operator or the like, and a controller 300 including a determination unit for determining whether the object to be detected comes close to any of the operation switches of the switch row 20 on the basis of the detection results of the electrostatic detection sensors.

The plurality of operation switches (21, 22, 23, and 24) are arranged in parallel and constitutes the switch row 20. The first electrostatic detection sensor 12 and the second electrostatic detection sensor 14 are disposed on both sides (the upper and lower sides of the sheet of FIG. 2) of the switch row 20. The first electrostatic detection sensor 12 and the second electrostatic detection sensor 14 can detect two dimensional coordinate values in the sheet of FIG. 2. In addition, the first electrostatic detection sensor 12 and the second electrostatic detection sensor 14 can detect the two dimensional coordinate values of an object to be detected in close proximity such as a finger of an operator or the like, capacitance values or corresponding voltage values on the coordinates, or the like.

In FIGS. 1A and 2, the controller 300 that controls a sensor panel 10 includes a driving unit 310 for driving a Y electrode unit 210 (second detection-electrode group 200) and a reading unit 320 for reading capacitance from an X electrode unit 110 (first detection-electrode group 100).

The driving unit 310 is configured to sequentially supply voltage to the Y electrode unit 210 (second detection-electrode group 200) in the form of a periodic electrical current based on a drive signal 51 outputted from the controller 300.

The reading unit 320 is configured to sequentially switch the connections to the X electrode unit 110 (first detection-electrode group 100) to read out capacitance while one Y electrode unit 210 (second detection-electrode group 200) is being driven. The reading unit 320 includes a threshold 330, compares the read capacitance with the threshold 330 to perform proximity detection, and output coordinates (X, Y) which is detection point information S2 including information on a close proximity detection point. The coordinates of the detection points are calculated by means of weight average, for example.

### Controller 300

The controller 300 is, for example, a microcomputer including a central processing unit (CPU) and a semiconductor memory such as random access memory (RAM) and a read only memory (ROM), and the like. As described above, the controller 300 outputs a driving signal S1 to the driving unit 310 to drive electrodes and obtains coordinates (X, Y) which is the detection point information S2 of detection points.

In addition, the controller 300 is connected to an air conditioning device 510, an audio device 520, and the like via a vehicle-mounted LAN 400 such as LIN and CAN.

The sensor panel 10 of the operation device according to an embodiment obtains, by mutual capacitance method, coordinates (X, Y) which is the detection point information S2 of detection points. In the mutual capacitance method, a finger or the like moving closer causes variation of mutual capacitance generated at each intersecting point between the Y electrode unit 210 (second detection-electrode group 200) and the X electrode unit 110 (first detection-electrode group 100). The variation is detected by sequentially driving the Y electrode unit 210 (second detection-electrode group 200) and the X electrode unit 110 (first detection-electrode group 100) to detect a proximate position or a touch position.

### Base Film 50

As illustrated in FIGS. 2 and 3A, the base film 50 serves as a base on which the first detection-electrode group 100 and the second detection-electrode group 200 are formed, holds the first detection-electrode group 100 and the second detection-electrode group 200 in a thickness direction with a substantially regular interval therebetween, and functions as an insulation layer for insulation. The base film 50 is made of a film-like insulator having a thickness (the thickness in general is approximately from 12 μm to 50 μm) and provides a flexible printed circuit (FPC). The base film 50 is provided on one side thereof with a first detection-electrode group 100 made of a conductive material and on the other side thereof with the second detection-electrode group 200 made of a conductive material. Wiring units 120 and 220 drawn respectively from the first detection-electrode group 100 and the second detection-electrode group 200 are electrically connected to the reading unit 320 and the driving unit 310. The base film 50 is made of resin such as polyimide, for example, and has a predetermined dielectric constant. The base film 50 is sandwiched between the first and second detection-electrode groups 100, 200. The base film 50 functions as a capacitor, providing a predetermined capacitance at an intersection point between the base film 50 and the first detection-electrode group 100 and at an intersection point between the base film 50 and the second detection-electrode group 200. The first and second detection-electrode groups 100 and 200 will be described further below.

As illustrated in FIGS. 2 and 3A, the base film 50 has a loop-like shape. Specifically, the base film 50 has a rectangular outer profile (such as an oblong or square shape) and a center hole area 52 hollowed or formed in the center part of the base film 50. The shape of the loop-like shape is determined so that the loop-like shape can comply to any constraints on the arrangement and the dimensions of the instrument to which the base film is attached. The shape of the base film 50 is used to determine the shapes of first and second detection-electrode groups 100, 200 described below.

### First Detection-Electrode Group 100

A first detection-electrode group 100 is made of a conductive material, includes multiple detection electrodes disposed in the first direction, and is laid on the base film 50. Variation of a capacitance value determined at an intersection point with a second detection-electrode group 200 detects a coordinate in a first direction. As illustrated in FIGS. 2, 3A, and 3B, the first direction or X direction and the second direction or Y direction intersect with each other. The first detection-electrode group 100 includes multiple electrodes in the X direction at regular intervals so that it can detect a coordinate in the X direction.

The first detection-electrode group 100 includes a transparent electrode such as indium tin oxide (ITO). Alternatively, other conductive materials including copper foil can be employed depending on the installation position of the second detection-electrode group 200.

As illustrated in FIGS. 2 and 3A, the first detection-electrode group 100 is composed of an X electrode unit 110 formed in accordance with the rectangular shape of the base film 50, and a wiring unit 120 for providing wiring from the X electrode unit 110 to a controller. As illustrated in FIGS. 2 and 3A, a lower side part 131, a right side part 132 and a left side part 133 of the X electrode unit 110 are directly wired in a downward direction. An upper side part 134 of the X electrode unit 110 corresponding to an upper side of the base film 50 is wired in an upward direction, then diverged into the sides of the right side part 132 and the left side part 133, and is wired in a downward direction. Such a wiring configuration can comply to any constraints on the arrangement and dimensions of the base film 50 having the center hole area 52. The wiring configuration or method described above can be modified depending on the constraints on the arrangement and dimensions of the base film 50.

### Second Detection-electrode Group 200

The second detection-electrode group 200 is made of a conductive material, includes multiple detection electrodes disposed in the first direction, and is laid on the base film 50. Variation of a capacitance value determined at an intersection point with the first detection-electrode group 100 detects a coordinate in a second direction. As illustrated in FIGS. 2, 3A, and 3B, the X direction or the first direction, and the Y direction or the second direction intersect with each other, and the second detection-electrode group 200 includes multiple electrodes in the Y direction at regular intervals so that it can detect a coordinate in the Y direction.

The second detection-electrode group 200 includes a transparent electrode such as indium tin oxide (ITO). Alternatively, other conductive materials including copper foil can be employed depending on the installation position of the second detection-electrode group 200.

As illustrated in FIGS. 2 and 3B, the second detection-electrode group 200 includes a Y electrode unit 210 shaped conforming to the rectangular shape of the base film 50, and a wiring unit 220 for providing wiring from the Y electrode unit 210 to a controller. As illustrated in FIGS. 2 and 3B, a lower side part 231 and a right side part 232 of the Y electrode unit 210 respectively corresponding to a lower side part and a right side part of the base film 50 are guided to the side of the right side part 231 and are wired in a downward direction. A left side part 233 and a right side part 234 of the Y electrode unit 210 corresponding to a left side part and a right side part, respectively, of the base film 50 are guided to the side of the left side part 233 and are wired in a downward direction. Such a wiring configuration can comply to any constraints on the arrangement and dimensions of the base film 50 having the center hole area 52. The wiring configuration or method described above can be modified depending on the constraints on the arrangement and dimensions of the base film 50.

### Application Example of First Embodiment

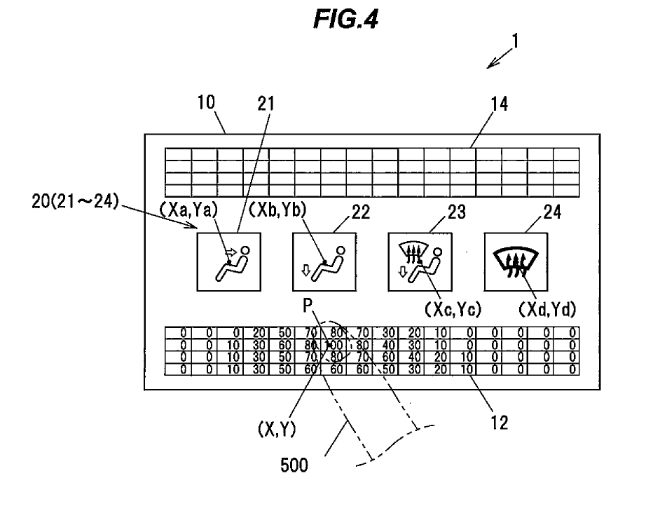

As illustrated in FIG. 1B, the operation device according to the present embodiment is employed for a vehicle-mounted air conditioning device. FIG. 4 is a plan view illustrating an example of capacitance distribution on the sensor panel in a case where a finger comes close to the sensor panel during the operation of the operation device according to the first embodiment of the invention.

As illustrated in FIG. 4, the sensor panel 10, for example, is attached to a front surface of the operation device for operating an air conditioning device 510 mounted on a vehicle. As illustrated in FIGS. 2 to 4, the sensor panel 10, as described above, is integrally formed in panel-like shape by stacking the first detection-electrode group 100, the second detection-electrode group 200, and the base film 50. The aforementioned switch row 20 (the operation switches 21, 22, 23, and 24) is disposed in a center hole area 52 of the base film 50 of the sensor panel 10. When an operator brings his/her finger 500 close to the front surface of the operation device with the intention of operating the operation device, the sensor panel 10 can detect the proximate position of his/her finger 500 as X and Y coordinate values and capacitance values on the coordinates (output values such as voltage values corresponding to the capacitance values or the like). This can determine which of the operation switches 21, 22, 23, and 24 the operator is going to operate, that is, the operation intention of the operator.

### Detection Operation

The controller 300 performs a detection operation using the determination unit on the basis of the following processing as an algorithm. First, the controller 300 detects a count value of the capacitance value exceeding the threshold 330, at coordinates X and Y on the first detection-electrode group 100 and the second detection-electrode group 200. That is, when the finger 500 comes close to the sensor panel 10 from the downward direction, as illustrated in FIG. 4, the distribution of the count value of the capacitance value of an area to which the finger 500 comes close to the operation switch 22 can be obtained, for example. The distribution of the count value of the capacitance value exceeding the threshold 330 is formed in accordance with the proximity operation of a fingertip.

The controller 300, as illustrated in FIG. 4, calculates the detection coordinates (X, Y) with a proximity point P as a center point (or the center of gravity) from the distribution of the count value of the capacitance value.

In contrast, the center position coordinates of each of the operation switches (21, 22, 23, and 24) are stored in a storage of the controller 300 as (Xa, Ya), (Xb, Yb), (Xc, Yc), and (Xd, Yd), respectively. Thus, the controller 300 can determine which of the operation switches (21, 22, 23, and 24) is close to the proximity point P (X, Y) by calculating a distance between the detection coordinates (X, Y) and each of the center position coordinates (Xa, Ya), (Xb, Yb), (Xc, Yc), and (Xd, Yd).

In the aforementioned detection operation, the position of the fingertip can be determined by the proximity operation in real time by appropriately setting the drive time of the driving unit 310 and the reading unit 320 by means of the controller 300. This enables a proximity detection as to which of the operation switches (21, 22, 23, and 24) the operator is going to operate.

FIG. 4 is an example where the operator brings his/her finger 500 closer to the operation switch from the downward direction, but when the operator brings his/her finger 500 closer to the operation switch from the upward direction, the second electrostatic detection sensor 14 detects a proximity point P (X, Y). Thus, in the configuration in which the electrostatic detection sensors (the first electrostatic detection sensor 12 and the second electrostatic detection sensor 14) are disposed on the upper side or the lower side of the switch row 20, the proximity detection can be performed in whichever direction the finger 500 comes close to the switch row 20.

### Modification

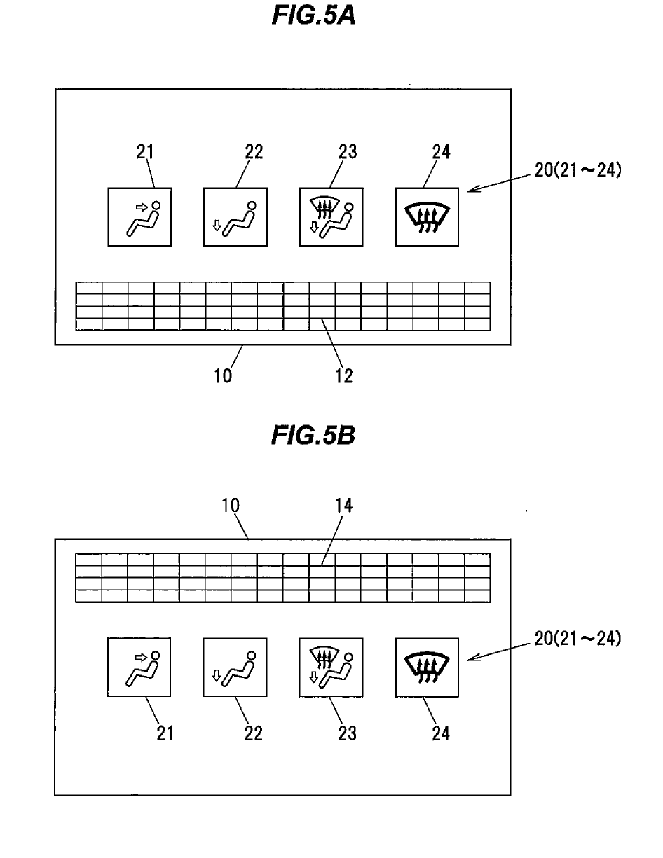

FIGS. 5A and 5B are plan views illustrating a configuration of a sensor panel representing the modification of the operation device according to the first embodiment of the invention. FIG. 5A is an example where the electrostatic detection sensor (the first electrostatic detection sensor 12) is disposed only on the lower side of the switch row 20 (the operation switches 21, 22, 23, and 24). In addition, FIG. 5B is an example where the electrostatic detection sensor (the second electrostatic detection sensor 14) is disposed only on the upper side of the switch row 20 (the operation switches 21, 22, 23, and 24). For example, when the sensor panel 10 is disposed in an instrument panel in a vehicle and the like, there is a case where it is determined that from which direction the operator brings his/her finger closer to the sensor panel 10 to be operated. In this case, it is possible to employ the configuration in which the electrostatic detection sensor is disposed only on the lower side or only on the upper side of the switch row 20, as in the modification.

### Effect of First Embodiment

According to the first embodiment, when the proximity operation of a finger for each operation switch is performed, proximity detection can be performed by disposing the electrostatic detection sensor that can detect a position and coordinates in the periphery of the operation switch without disposing electrodes in the operation switch. This makes it possible to provide the operation device including the electrostatic detection sensors that can perform proximity detection from the periphery of the switch row on the front surface of the operation device. In particular, when the operation device is used in a vehicle, there is a case where the switch row includes the operation switches placed in parallel on the left and on the right. In addition, in many cases, the operation device is operated from a driver's seat and a passenger's seat, thus the configuration according to the present embodiment in which the electrostatic detection sensors are disposed on the lower side and the upper side of the switch row arranged in parallel laterally is effective.

### Second Embodiment of Invention

In the second embodiment of the invention, the controller 300 is configured to determine whether an object to be detected comes close to any of the operation switches of the switch row on the basis of a temporal change of two-dimensional coordinate values from the electrostatic detection sensors.

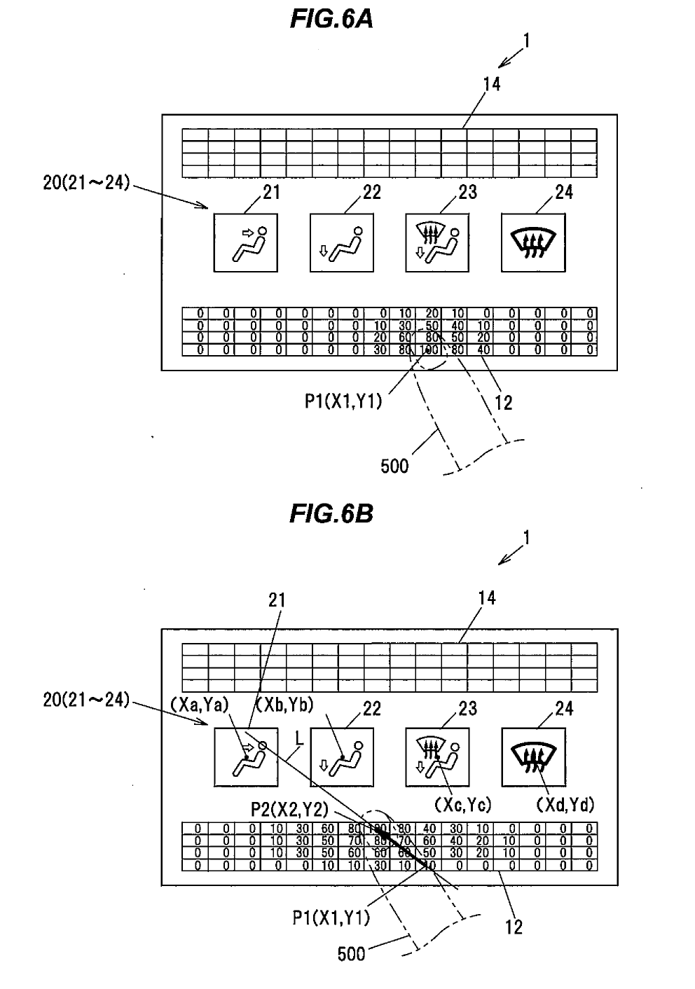

FIG. 6A is a plan view illustrating a sensor panel of an operation device according to the second embodiment of the invention, and FIG. 6B is a plan view illustrating a state where a finger in close proximity moves to an operation switch.

In the second embodiment of the invention, the controller 300 detects the temporal change of two-dimensional coordinate values with the electrostatic detection sensors and determines to which operation switches the object to be detected comes close on the basis of the detection. Various methods are conceivable as the determination method, and one example of the determination method is described below.

### Detection Operation

The controller 300 detects a count value of the capacitance value exceeding the threshold 330, at coordinates X and Y on the first detection-electrode group 100 and the second detection-electrode group 200. That is, when a finger comes close to the sensor panel 10 from the downward direction, as illustrated in FIG. 6A, the distribution of the count value of the capacitance value of an area to which the finger comes close to the operation switch 23 can be obtained, for example. The distribution of the count value of the capacitance value exceeding the threshold 330 is formed in accordance with the proximity operation of a fingertip.

The controller 300, as illustrated in FIG. 6A, calculates the detection coordinates (X1, Y1) with a proximity point P1 as a center point (or the center of gravity) from the distribution of the count value of the capacitance value.

A similar detection operation is performed at regular time intervals. The controller 300 detects a count value of the capacitance value exceeding the threshold 330 at coordinates X and Y on the first detection-electrode group 100 and the second detection-electrode group 200. That is, when the finger comes close to the sensor panel 10 from the downward direction, as illustrated in FIG. 6B, the distribution of the count value of the capacitance value of an area to which the finger comes close to the operation switch 22 is obtained, for example. The distribution of the count value of the capacitance value exceeding the threshold 330 is formed in accordance with the proximity operation of a fingertip.

The controller 300, as illustrated in FIG. 6B, calculates the detection coordinates (X2, Y2) with a proximity point P2 as a center point (or the center of gravity) from the distribution of the count value of the capacitance value.

The controller 300 calculates a straight line L on the two-dimensional coordinates, as illustrated in FIG. 6B, from the detection coordinates P1 (X1, Y1) and the detection coordinates P2 (X2, Y2). That is, a direction vector of the straight line L is calculated from the detection coordinates P1 (X1, Y1) and the detection coordinates P2 (X2, Y2), and the straight line L can be calculated from this vector and the detection coordinates P1 (X1, Y1).

The controller 300 obtains the distance of a perpendicular distance of the straight line L from each of the center position coordinates (Xa, Ya), (Xb, Yb), (Xc, Yc), and (Xd, Yd) of the respective operation switches (21, 22, 23, and 24) illustrated in FIG. 6B. It can be determined that the finger comes close to the operation switch having the minimum value of the perpendicular distance, from among the operation switches (21, 22, 23, and 24).

The aforementioned proximity detection can be performed in real time by repeatedly executing the proximity detection.

FIGS. 6A and 6B are examples where the operator brings his/her finger closer to the operation switch from the downward direction, but when the operator brings his/her finger closer to the operation switch from the upward direction, the second electrostatic detection sensor 14 detects the proximity points P1 and P2. Thus, in the configuration in which the electrostatic detection sensors (the first electrostatic detection sensor 12 and the second electrostatic detection sensor 14) are disposed on the upper side or the lower side of the switch row 20, the proximity detection can be performed whichever direction the finger comes close to the switch row 20.

### Effects of Second Embodiment

According to the second embodiment of the invention, the controller 300 determines whether an object to be detected comes close to any of the operation switches of the switch row on the basis of the temporal change of two-dimensional coordinate values with the electrostatic detection sensors, so that the proximity of the finger can be determined with higher accuracy than that of the first embodiment.

### Third Embodiment of Present Invention

A third embodiment of the invention is configured such that two switch rows are arranged in parallel.

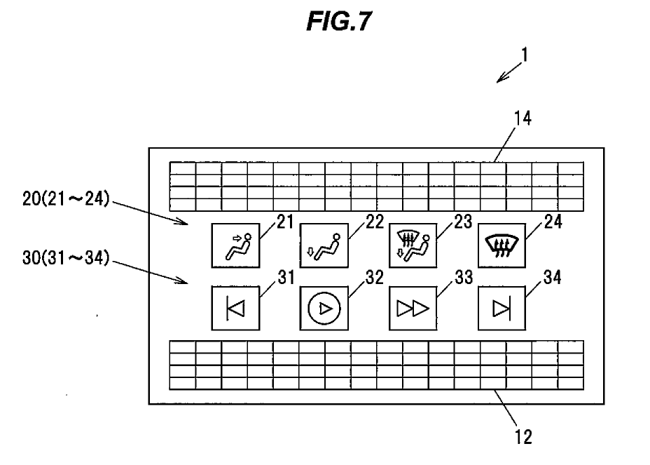

FIG. 7 is a plan view illustrating a sensor panel of an operation device according to the third embodiment of the invention. The upper switch row 20 (21, 22, 23, and 24), for example, is the operation switch for the air conditioning device of a vehicle, and the lower switch row 30 (31, 32, 33, and 34), for example, is the operation switch for the audio device of the vehicle.

The first electrostatic detection sensor 12 is disposed on the lower side of the two switch rows 20 and 30, and the second electrostatic detection sensor 14 is disposed on the upper side of the two switch rows 20 and 30. As is the same with the first and second embodiments, the proximity point P is detected from the distribution of the count value of the capacitance value. Alternatively, the proximity points P1 and P2 are detected at regular time intervals. This enables the proximity detection in real time, as is the same with the first embodiment and the second embodiment.

### Effects of Third Embodiment

According to the third embodiment, even with the configuration in which the two switch rows 20 and 30 are included, the first electrostatic detection sensor 12 is disposed on the lower side, and the second electrostatic detection sensor 14 is disposed on the upper side, so that the proximity of the finger can be determined with high accuracy.

The embodiments of the invention described above are merely examples and do not intend to limit the scope of the invention described in the claims. These novel embodiments may be implemented in various other forms, and various omissions, substitutions, changes, and the like can be made without departing from the spirit and scope of the invention. In addition, all the combinations of the features described in these embodiments are not necessarily needed to solve the technical problem. Further, these embodiments are included within the spirit and scope of the invention and also within the invention described in the claims and the scope of equivalents thereof.

### REFERENCE SIGNS LIST

1 Operation device
10 Sensor panel
12 First electrostatic detection sensor
14 Second electrostatic detection sensor
20, 30 Switch row
21, 22, 23, 24, 31, 32, 33, 34 Operation switch
300 Controller

1. An operation device, comprising:
a switch row in which operation switches are disposed;
an electrostatic detection sensor disposed on an upper side or a lower side of the switch row and configured to detect two-dimensional coordinate values of an object to be detected coming close to the switch row; and
a controller including a determination unit configured to determine which of the operation switches of the switch row is close to the object to be detected, based on a detection result of the electrostatic detection sensor.

2. The operation device according to claim 1, wherein the controller is configured to determine which of the operation switches of the switch row is close to the object to be detected, based on a temporal change of the two-dimensional coordinate values from the electrostatic detection sensor.

3. The operation device according to claim 1, wherein the electrostatic detection sensor includes a first electrostatic detection sensor and a second electrostatic detection sensor disposed on an upper side and a lower side of the switch row, and
wherein the controller is configured to determine which of the operation switches of the switch row is close to the object to be detected, based on detection results of the first electrostatic detection sensor and the second electrostatic detection sensor.

4. The operation device according to claim 1, wherein the electrostatic detection sensor comprises a mutual capacitance type electrostatic detection sensor.

5. The operation device according to claim 1, wherein the electrostatic detection sensor is formed outside of an area where the switch row is disposed.

6. The operation device according to claim 1, wherein the electrostatic detection sensor has a width exceeding a width of the switch row along a longitudinal direction.
